(19) United States
(12) Patent Application Publication
(10) Pub. No.: US 2024/0290925 A1
(43) Pub. Date: Aug. 29, 2024

(54) Display Device

(71) Applicant: LG Display Co., Ltd., Seoul (KR)

(72) Inventors: Sangmin Park, Gimpo-si (KR); ChangBae Park, Goyang-si (KR); Bogyun Chung, Goyang-si (KR); Gwangmin Yeo, Goyang-si (KR)

(21) Appl. No.: 18/432,738

(22) Filed: Feb. 5, 2024

(30) Foreign Application Priority Data
Feb. 28, 2023 (KR) 10-2023-0026747

(51) Int. Cl. H01L 33/62; H01L 25/16; H01L 33/54

(52) U.S. Cl. CPC H01L 33/62; H01L 25/167; H01L 33/54

(57) ABSTRACT

A display device is disclosed. The display device comprises a display panel including a plurality of subpixels; a light emitting diode in a subpixel from the plurality of sub pixels; a first planarization layer that encloses the light emitting diode; a second planarization layer on the first planarization layer and the light emitting diode; and a connection electrode on the second planarization layer and connected to the light emitting diode. The first planarization layer includes a first open area that encloses the light emitting diode and a portion of the first planarization layer corresponding to the first open area has a first thickness that is less than a second thickness of a second portion of the first planarization layer.

### CROSS-REFERENCE TO RELATED APPLICATION

This application claims the priority of Republic of Korea Patent Application No. 10-2023-0026747 filed on Feb. 28, 2023, in the Korean Intellectual Property Office, which is hereby incorporated by reference in its entirety.

### BACKGROUND

### Field

The present disclosure relates to a display device, and more particularly, to a display device using a light emitting diode (LED).

### Description of the Related Art

As display devices which are used for a monitor of a computer, a television, or a cellular phone, there are an organic light emitting display (OLED) device which is a self-emitting device, a liquid crystal display (LCD) device which requires a separate light source, and the like that are included in the display devices.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast-lighting speed, excellent luminous efficiency, and a strong impact resistance so that a stability is excellent and an image having a high luminance can be displayed.

### SUMMARY

An object to be achieved by the present disclosure is to provide a display device which ensures a contact area of an electrode of a light emitting diode when a transferring location is dislocated or misaligned during a process of transferring a light emitting diode onto a display panel.

Another object to be achieved by the present disclosure is to minimize or at least reduce a residual film generated when a contact hole for exposing an electrode of the light emitting diode is formed and ensure a contact hole area.

Still another object to be achieved by the present disclosure is to provide a display device which solves a short problem from a connection electrode due to the semiconductor layer of the light emitting diode exposed when a transferring location is dislocated or misaligned during a process of transferring the light emitting diode.

Objects of the present disclosure are not limited to the above-mentioned objects, and other objects, which are not mentioned above, can be clearly understood by those skilled in the art from the following descriptions.

In one embodiment, a display device comprises: a display panel including a plurality of subpixels; a light emitting diode in a subpixel from the plurality of subpixels; a first planarization layer that encloses the light emitting diode; a second planarization layer on the first planarization layer and the light emitting diode; and a connection electrode on the second planarization layer, the connection electrode connected to the light emitting diode, wherein the first planarization layer includes a first open area that encloses the light emitting diode and a portion of the first planarization layer corresponding to the first open area has a first thickness that is less than a second thickness of a second portion of the first planarization layer.

In one embodiment, a display device comprises: a substrate; a thin film transistor on the substrate; a lower planarization layer on the thin film transistor; a light emitting diode configured to emit light, the light emitting diode electrically connected to the thin film transistor; a first planarization layer that encloses the light emitting diode and includes a first portion that is in direct contact with a portion of a side surface of the light emitting diode and a second portion that extends from the first portion, the first portion of the first planarization layer having a thickness that is less than a thickness of the second portion of the first planarization layer; and a second planarization layer that is on the light emitting diode and the first planarization layer.

Other detailed matters of the exemplary embodiments are included in the detailed description and the drawings.

According to the present disclosure, an encapsulation layer which protects the light emitting diode is torn during the transferring process of the light emitting diode so that a short or contact failure problem to be generated later may be solved.

According to the present disclosure, when the transferring location is dislocated or misaligned during the process of transferring the light emitting diode, through the first planarization layer formed by a photolithographic process using a halftone mask, a lower side surface of a semiconductor of the light emitting diode is suppressed from being exposed.

According to the present disclosure, when the transferring location is dislocated or misaligned during the process of transferring the light emitting diode, a structure which allows the electrode of the light emitting diode to be stably contacted may be provided.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a plan view of a display panel of a display device according to an exemplary embodiment of the present disclosure;

FIGS. 4A to 4C are plan views illustrating a pixel area of a display device according to an exemplary embodiment of the present disclosure;

FIG. 5 is a cross-sectional view of a display device according to an exemplary embodiment of the present disclosure;

FIG. 6A is a schematic plan view for explaining a light emitting diode of one sub pixel and a planarization layer to explain a display device according to a comparative embodiment;

FIGS. 6B and 6C are schematic cross-sectional views for explaining a display device according to a comparative embodiment;

FIGS. 7A to 7G are schematic cross-sectional views for explaining a manufacturing method of a display device according to an exemplary embodiment of the present disclosure;

FIG. 8 is a cross-sectional view for explaining a display device according to another exemplary embodiment of the present disclosure; and

FIG. 9 is a cross-sectional view for explaining a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

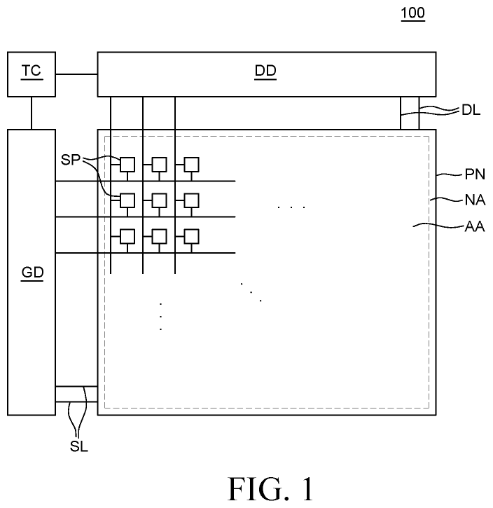

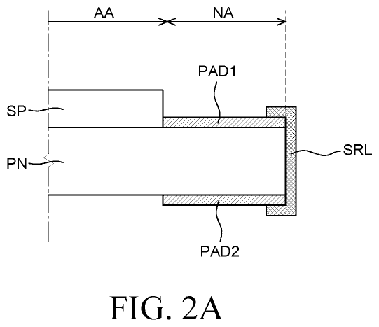

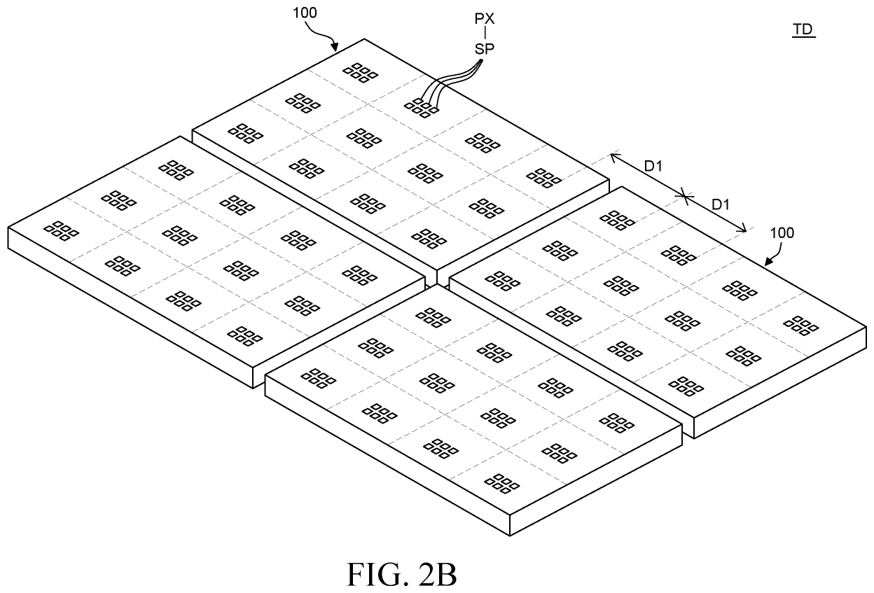

FIG. 1 is a schematic diagram of a display device according to an exemplary embodiment of the present disclosure. FIG. 2A is a partial cross-sectional view of a display device according to an exemplary embodiment of the present disclosure. FIG. 2B is a perspective view of a tiling display device according to an exemplary embodiment of the present disclosure. In FIG. 1, for the convenience of description, among various components of the display device 100, a display panel PN, a gate driver GD, a data driver DD, and a timing controller TC are illustrated.

Referring to FIG. 1, the display device 100 includes a display panel PN including a plurality of sub pixels SP, a gate driver GD, and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line VL1, a low potential power line VL2, and a reference line.

In the display panel PN, an active area AA and the non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP form one pixel PX. In each of the plurality of sub pixels SP, a light emitting diode 130 (e.g., a light emitting element) and a thin film transistor for driving the light emitting diode 130 may be disposed. The plurality of light emitting diodes 130 may be defined in different ways depending on the type of the display panel PN. For example, when the display panel PN is an inorganic light emitting display panel, the light emitting diode 130 may be a light emitting diode (LED) or a micro light emitting diode (LED).

In the active area AA, a plurality of wiring lines which transmits various signals to the plurality of sub pixels SP is disposed. For example, the plurality of wiring lines includes a plurality of data lines DL which supplies a data voltage to each of the plurality of sub pixels SP and a plurality of scan lines which supplies a scan signal to each of the plurality of sub pixels SP. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line VL2 and a high potential power line VL1 may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

However, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board. The data driver DD and the timing controller TC may be electrically connected to the display panel PN by bonding the flexible film and the printed circuit board to the pad electrode formed in the non-active area NA of the display panel PN.

If the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is necessary more than a predetermined level. Accordingly, a bezel may be increased.

In contrast, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel with substantially no bezel may be implemented.

Specifically, referring to FIGS. 2A and 2B, in the non-active area NA of the display panel PN, a plurality of pad electrodes for transmitting various signals to the plurality of sub pixels SP is disposed. For example, in the non-active area NA on the front surface (e.g., a first surface) of the display panel PN, a first pad electrode PAD1 which transmits a signal to the plurality of sub pixels SP is disposed. In the non-active area NA on the rear surface (e.g., a second surface) of the display panel PN, a second pad electrode PAD2 which is electrically connected to a driving component, such as a flexible film and the printed circuit board, is disposed. That is, on the front surface of the display panel PN on which images are displayed, a pad area of the non-active area NA in which the first pad electrode PAD1 is disposed may be formed at minimum.

In this case, even though it is not illustrated in the drawing, various signal lines connected to the plurality of sub pixels SP, for example, a scan line SL or a data line DL extends from the active area AA to the non-active area NA to be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN is transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize or reduce an area of the non-active area NA on the front surface of the display panel PN.

Further, referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP forms one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, a distance D1 between pixels PX between the display devices 100 is constantly configured to minimize the seam area.

However, FIGS. 2A and 2B are illustrative so that the display device 100 according to the exemplary embodiment of the present disclosure may be a general display device 100 with a bezel, but is not limited thereto.

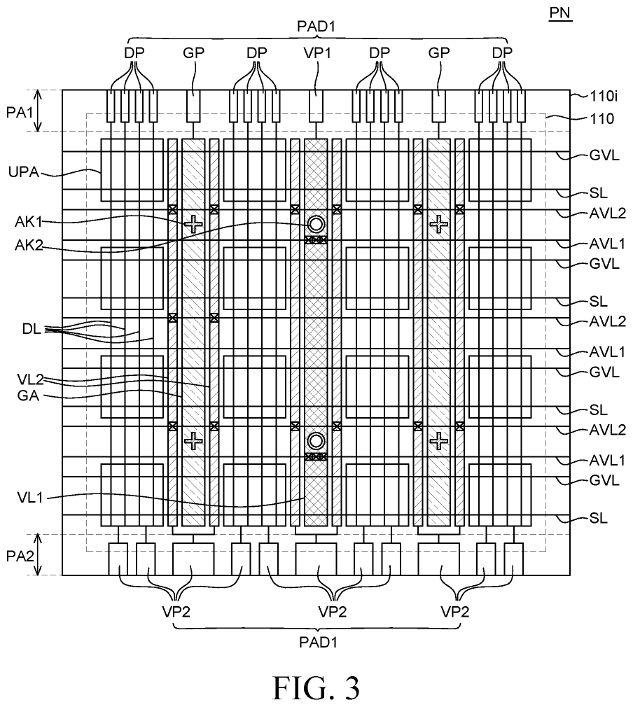

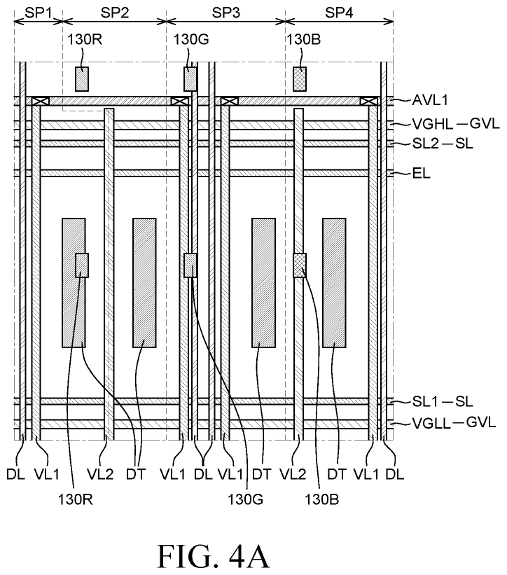

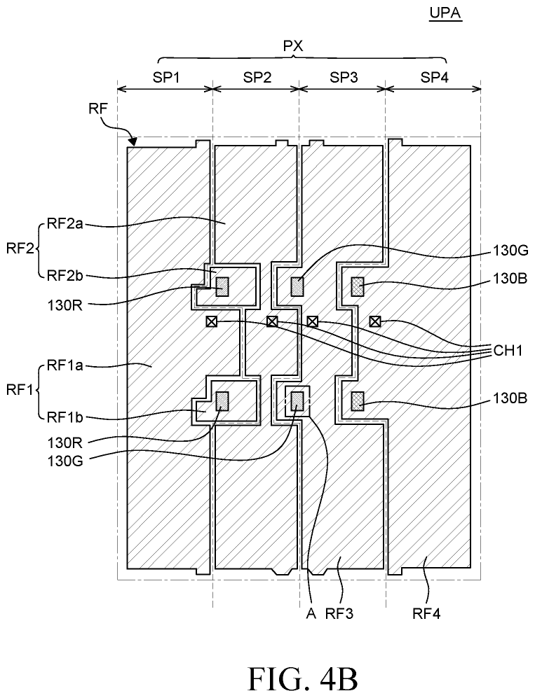

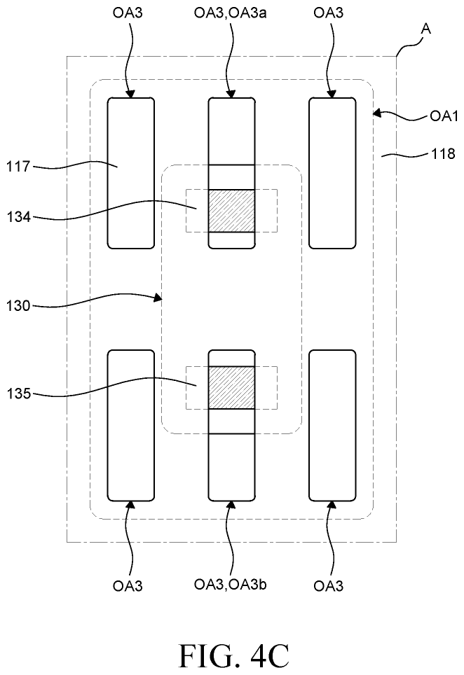

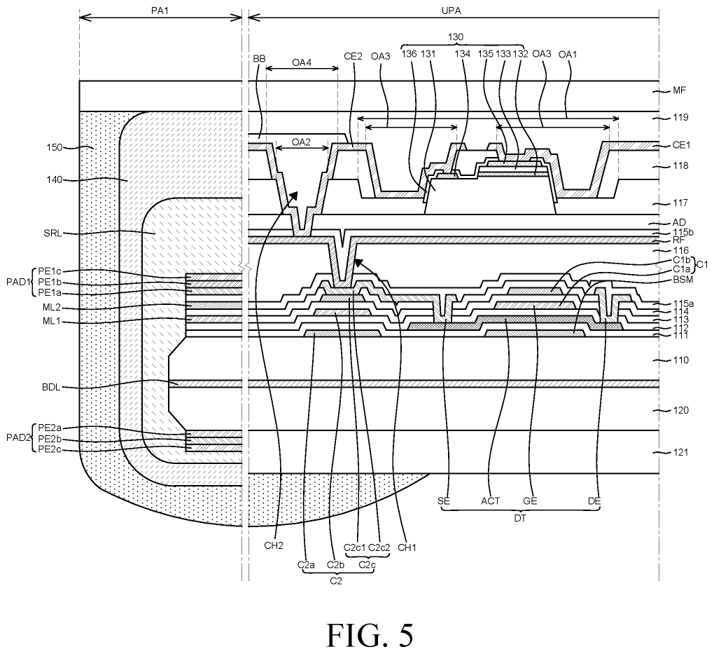

FIG. 3 is a plan view of a display panel of a display device according to an exemplary embodiment of the present disclosure. FIGS. 4A to 4C are plan views illustrating a pixel area of a display device according to an exemplary embodiment of the present disclosure. FIG. 5 is a cross-sectional view of a display device according to an exemplary embodiment of the present disclosure. For the convenience of description, in FIG. 4A, the plurality of light emitting diodes 130, a driving transistor DT of the pixel circuit, and a plurality of wiring lines are illustrated. Further, in FIG. 4B, a plurality of reflection plates RF and a plurality of light emitting diodes 130 are illustrated. FIG. 4C is a plan view for an area A of FIG. 4B and illustrates open areas of a first planarization layer 117 and a second planarization layer 118 with respect to a light emitting diode in one sub pixel.

First, referring to FIGS. 3 to 5, the display panel PN includes a first substrate 110. The first substrate 110 is a substrate which supports components disposed above the display device 100 and may be an insulating substrate. A plurality of pixels PX are formed on the first substrate 110 to display images. For example, the first substrate 110 may be formed of glass or resin. Further, the first substrate 110 may be formed of polymer or plastic. In some exemplary embodiments, the first substrate 110 may be formed of a plastic material having flexibility.

Referring to FIG. 3, in the first substrate 110, a plurality of pixel areas UPA, a plurality of gate driving areas GA, and a plurality of pad areas PA1 and PA2 are disposed. Among them, the plurality of pixel areas UPA and the plurality of gate driving areas GA may be included in the active area AA of the display panel PN.

First, the plurality of pixel areas UPA are areas in which the plurality of pixels PX are disposed. The plurality of pixel areas UPA may be disposed by forming a plurality of rows and a plurality of columns of pixel areas UPA. Each of the plurality of pixels PX disposed in the plurality of pixel areas UPA includes a plurality of sub pixels SP. Each of the plurality of sub pixels SP includes a light emitting diode 130 and a pixel circuit to independently emit light.

The plurality of gate driving areas GA are areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, the gate driver may include a plurality of transistors and/or capacitors. Here, active layers of the plurality of transistors may be formed of a semiconductor material, such as an oxide semiconductor, amorphous silicon, or polysilicon, but is not limited thereto. The active layers of the plurality of transistors may be formed of the same material or different materials from each other. Further, the active layers of the transistors of the gate driver may be formed of the same material as active layers of various transistors of the pixel circuit or formed of different materials from each other.

The plurality of pad areas PA1 and PA2 are areas in which a plurality of first pad electrodes PAD1 are disposed. The plurality of first pad electrodes PAD1 may transmit various signals to various wiring lines extending in a column direction in the active area AA. For example, the plurality of first pad electrodes PAD1 includes a data pad DP, a gate pad GP, a high potential power pad VP1, and a low potential power pad VP2. The data pad DP transmits a data voltage to the data line DL and the gate pad GP transmits a clock signal, a start signal, a gate low voltage, and a gate high voltage for driving the gate driver GD to the gate driver GD. The high potential power pad VP1 transmits a high potential power voltage to the high potential power line VL1 and the low potential power pad VP2 transmits a low potential power voltage to the low potential power line VL2.

The plurality of pad areas PA1 and PA2 includes a first pad area PA1 located at an upper edge and a second pad area PA2 of the display panel PN. At this time, in the first pad area PA1 and the second pad area PA2, different types of first pad electrodes PAD1 may be disposed. For example, in the first pad area PA1, among the plurality of first pad electrodes PAD1, the data pad DP, the gate pad GP, and the high potential power pad VP1 are disposed and in the second pad area PA2, the low potential power pad VP2 may be disposed.

At this time, the plurality of first pad electrodes PAD1 may be formed to have different sizes. For example, the plurality of data pads DP which is connected to the plurality of data lines DL one to one may have a relatively narrower width and the high potential power pad VP1, the low potential power pad VP2, and the gate pad GP may have a relatively larger width. However, widths of the data pad DP, the gate pad GP, the high potential power pad VP1, and the low potential power pad VP2 illustrated in FIG. 3 are illustrative so that the first pad electrode PAD1 may be configured in various sizes, but is not limited thereto.

In the meantime, in order to reduce the bezel of the display panel PN, an edge of the display panel PN may be cut to be removed. The plurality of pixels PX, the plurality of wiring lines, and the plurality of first pad electrodes PAD1 are formed on an initial first substrate 110i and an edge part of the initial first substrate 110i is ground to reduce the bezel area. During the grinding process, a part of the initial first substrate 110i is removed to form a first substrate 110 with a smaller size. At this time, parts of the plurality of first pad electrodes PAD1 and wiring lines disposed at the edge of the first substrate 110 may be removed. Accordingly, a part of the plurality of first pad electrodes PAD1 may remain on the first substrate 110.

Next, the plurality of data lines DL which extends in a column direction from the plurality of first pad electrodes PAD1 is disposed on the first substrate 110 of the display panel PN. The plurality of data lines DL extends from the plurality of data pads DP of the first pad area PA1 toward the plurality of pixel areas UPA. The plurality of data lines DL extends in a column direction and is disposed to overlap the plurality of pixel areas UPA. Therefore, the plurality of data lines DL may transmit the data voltage to the pixel circuit of each of the plurality of sub pixels SP.

The plurality of high potential power lines VL1 extending in the column direction is disposed on the first substrate 110 of the display panel PN. Some of the plurality of high potential power lines VL1 extends from the high potential power pad VP1 of the first pad area PA1 to the plurality of pixel areas UPA to transmit the high potential power voltage to the light emitting diodes 130 of the plurality of sub pixels SP. Further, the others of the plurality of high potential power lines VL1 are electrically connected to the other high potential power line VL1 by means of an auxiliary high potential power line AVL1 to be described below. In FIG. 3, for the convenience of description, even though it is illustrated that one high potential power line VL1 and one high potential power pad VP1 are disposed, a plurality of high potential power lines VL1 and high potential power pads VP1 may be disposed.

The plurality of low potential power lines VL2 extending in the column direction is disposed on the first substrate 110 of the display panel PN. At least some of the plurality of low potential power lines VL2 extends from the low potential power pad VP2 of the second pad area PA2 to the plurality of pixel areas UPA to transmit the low potential power voltage to the pixel circuit of each of the plurality of sub pixels SP. Further, the others of the plurality of low potential power lines VL2 may be electrically connected to the other low potential power line VL2 by means of an auxiliary low potential power line AVL2 to be described below.

The plurality of scan lines SL extending in the row direction is disposed on the first substrate 110 of the display panel PN. The plurality of scan lines SL extend in the row direction and may be disposed across the plurality of pixel areas UPA and the plurality of gate driving areas GA. The plurality of scan lines SL may transmit the scan signal from the gate driver GD to the pixel circuits of the plurality of sub pixels SP.

A plurality of auxiliary high potential power lines AVL1 extending in the row direction are disposed on the first substrate 110 of the display panel PN. The plurality of auxiliary high potential power lines AVL1 may be disposed in an area between the plurality of pixel areas UPA. The plurality of auxiliary high potential power lines AVL1 extending in the row direction are electrically connected to the plurality of high potential power lines VL1 extending in the column direction through a contact hole and forms a mesh structure. Therefore, the plurality of auxiliary high potential power lines AVL1 and the plurality of high potential power lines VL1 are configured to form a mesh structure to minimize or reduce voltage drop and voltage deviation.

A plurality of auxiliary low potential power lines AVL2 extending in the row direction are disposed on the first substrate 110 of the display panel PN. The plurality of auxiliary low potential power lines AVL2 may be disposed in an area between the plurality of pixel areas UPA. The plurality of auxiliary low potential power lines AVL2 extending in the row direction is electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize or reduce voltage deviation.

Referring to FIGS. 3 and 4A, the plurality of gate driving lines GVL extending in the row direction and the column direction are disposed on the first substrate 110 of the display panel PN. Some of the plurality of gate driving lines GVL extends from the gate pad GP of the first pad area PA1 to the gate driving area GA to transmit a signal to the gate driver GD. The others of the plurality of gate driving lines GVL extend in the row direction and transmit the signal to the gate drivers GD of the plurality of gate driving areas GA. Therefore, various signals are transmitted from the gate driving line GVL to the gate driver GD to drive the gate driver GD.

The plurality of gate driving lines GVL may include wiring lines which transmit a clock signal, a start signal, a gate high voltage, and a gate low voltage to the gate driver GD. Therefore, various signals are transmitted from the gate driving line GVL to the gate driver GD to drive the gate driver GD.

For example, referring to FIG. 4A, the plurality of gate driving lines GVL may include a gate power line which transmits a power voltage to the gate driver GD of the gate driving area GA. The plurality of gate power lines includes a first gate power line VGHL-GVL which transmits a gate high voltage to the gate driver GD and a second gate power line VGLL-GVL which transmits a gate low voltage to the gate driver GD.

A plurality of alignment keys AK1 and AK2 are disposed in an area between the plurality of pixel areas UPA in the display panel PN. The plurality of alignment keys AK1 and AK2 are used for alignment during the manufacturing process of the display panel PN. The plurality of alignment keys includes a first alignment key AK1 and a second alignment key AK2.

The first alignment key AK1 may be disposed in the gate driving area GA between the plurality of pixel areas UPA. The first alignment key AK1 may be used to inspect an alignment position of the plurality of light emitting diodes 130. For example, the first alignment key AK1 may have a cross shape, but is not limited thereto.

The second alignment key AK2 may be disposed to overlap the high potential power line VL1 between the plurality of pixel areas UPA. In the high potential power line VL1, a hole overlapping the second alignment key AK2 is formed to divide the second alignment key AK2 and the high potential power line VL1. The second alignment key AK2 may be used to align the display panel PN and a donor. The display panel PN and the donor are aligned using the second alignment key AK2 and the plurality of light emitting diodes 130 of the donor is transferred onto the display panel PN. For example, the second alignment key AK2 may have a circular ring shape, but is not limited thereto.

Hereinafter, the plurality of sub pixels SP of the pixel area UPA will be described in more detail with reference to FIGS. 4A to 5.

Referring to FIGS. 4A and 4B, in one pixel area UPA, a plurality of sub pixels SP which forms one pixel PX are disposed. For example, the plurality of sub pixels SP may include a first sub pixel SP1, a second sub pixel SP2, a third sub pixel SP3, and a fourth sub pixel SP which emit different color light. For example, the first sub pixel SP1 and the second sub pixel SP2 are red sub pixels SP that emit red light, the third sub pixel SP3 is a green sub pixel SP that emits green light, and the fourth sub pixel SP is a blue sub pixel SP that emits blue light, but it is not limited thereto.

Hereinafter, the description will be made by assuming that one pixel PX includes one first sub pixel SP1, one second sub pixel SP2, one third sub pixel SP3, and one fourth sub pixel SP, that is, two red sub pixels SP, one green sub pixel SP, and one blue sub pixel SP. However, the configuration of the pixel PX is not limited thereto.

Referring to FIG. 4A, as described above, a plurality of wiring lines which supplies various signals to the plurality of sub pixels SP are disposed in the plurality of pixel areas UPA of the first substrate 110. For example, the plurality of data lines DL, the plurality of high potential power lines VL1, and the plurality of low potential power lines VL2 extending in the column direction may be disposed on the first substrate 110. For example, the plurality of emission control signal lines EL, the plurality of auxiliary high potential power lines AVL1, the plurality of auxiliary low potential power lines AVL2, the plurality of first scan lines SL1, and the plurality of second scan lines SL2 extending in the row direction are disposed on the first substrate 110. Further, the high potential power line VL1 extending in the column direction may be electrically connected to the auxiliary high potential power line AVL1 extending in the row direction through a contact hole. At this time, the emission control signal line EL transmits an emission control signal to the pixel circuits of the plurality of sub pixels SP to control emission timings of the plurality of sub pixels SP.

Further, some gate driving lines GVL which transmit signals to the plurality of gate drivers GD disposed to be spaced apart from each other with the pixel area UPA therebetween may be disposed across the pixel area UPA while extending to the row direction. For example, a first gate power line VGHL-GVL which supplies a gate high voltage to the gate driver GD and a second gate power line VGLL-GVL which supplies a gate low voltage may be disposed across the pixel area UPA.

In the meantime, even though it is illustrated that the plurality of scan lines SL includes a first scan line SL1-SL and a second scan line SL2-SL, the configuration of the plurality of scan lines SL may vary depending on the pixel circuit configuration of the sub pixel SP, but is not limited thereto.

The pixel circuit for driving the light emitting diode is disposed in each of the plurality of sub pixels SP on the first substrate 110. The pixel circuit may include a plurality of thin film transistors and a plurality of capacitors. In FIGS. 4A and 5, for the convenience of description, a driving transistor DT, a first capacitor C1, and a second capacitor C2, among configurations of the pixel circuit are illustrated. However, the pixel circuit may further include a switching transistor, a sensing transistor, and an emission control transistor, but is not limited thereto.

First, a light shielding layer BSM is disposed on the first substrate 110. The light shielding layer BSM blocks light which is incident to an active layer ACT of the plurality of transistors to minimize or reduce a leakage current. For example, the light shielding layer BSM is disposed below the active layer ACT of the driving transistor DT to block light incident onto the active layer ACT. If light is irradiated onto the active layer ACT, leakage current is generated, which deteriorates the reliability of the transistor. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 may reduce permeation of moisture or impurities through the first substrate 110. The buffer layer 111 may be configured by a single layer or a double layer of silicon oxide SiOx or silicon nitride SiNx, but is not limited thereto. However, the buffer layer 111 may be omitted depending on a type of the first substrate 110 or a type of the thin film transistor, but is not limited thereto.

A driving transistor DT including an active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, or polysilicon, but is not limited thereto. Further, even though it is not illustrated in the drawings, another transistors, such as a switching transistor, a sensing transistor, and an emission control transistor, other than the driving transistor DT, may be further disposed. The active layers of the transistors are also formed of a semiconductor material, such as an oxide semiconductor, amorphous silicon, or polysilicon, but are not limited thereto. Further, the active layer of the transistor included in the pixel circuit, such as the driving transistor DT, the switching transistor, the sensing transistor, and the emission control transistor, may be formed of the same material, or formed of different materials.

The gate insulating layer 112 is disposed on the active layer ACT. The gate insulating layer 112 is an insulating layer which electrically insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact hole through which the source electrode SE and the drain electrode DE are connected to the active layer ACT are formed. The first interlayer insulating layer 113 and the second interlayer insulating layer 114 are insulating layers which protect components there below and may be configured by single layers or double layers of silicon oxide SiOx or silicon nitride SiNx, but is not limited thereto.

The source electrode SE and the drain electrode DE which are electrically connected to the active layer ACT are disposed on the second interlayer insulating layer 114. The source electrode SE is electrically connected to the second capacitor C2 and the first electrode 134 of the light emitting diode 130 and the drain electrode DE is electrically connected to the other configuration of the pixel circuit. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a is integrally formed with the gate electrode GE of the driving transistor DT. That is, the gate electrode GE is the 1-1-th capacitor electrode C1a.

The 1-2-th capacitor electrode C1b is disposed on the first interlayer insulating layer 113. The 1-2-th capacitor electrode C1b is disposed to overlap the 1-1-th capacitor electrode C1a with the second interlayer insulating layer 114 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode where the 2-2-th capacitor electrode C2b is between the 2-2-th capacitor electrode C2B and the 2-1-th capacitor electrode C2a.

The 2-1-th capacitor electrode C2a is disposed on the first substrate 110. The 2-1-th capacitor electrode C2a is disposed on the same layer as the light shielding layer BSM and may be formed of the same material.

The 2-2-th capacitor electrode C2b is disposed on the buffer layer 111 and the gate insulating layer 112. The 2-2-th capacitor electrode C2b is disposed on the same layer as the gate electrode GE and may be formed of the same material.

The 2-3-th capacitor electrode C2c is disposed on the first interlayer insulating layer 113. The 2-3-th capacitor electrode C2c may be configured by a first layer C2c1 and a second layer C2c2. The first layer C2c1 of the 2-3-th capacitor electrode C2c is formed on the same layer as the 1-2-th capacitor electrode C1b with the same material. The first layer C2c1 is disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part (e.g., a portion) extending from the source electrode SE of the driving transistor DT and may be connected to the first layer C2c1 through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and allow the light emitting diode 130 to emit light with a higher luminance.

A first passivation layer 115a is disposed on the driving transistor DT, the first capacitor C1, and the second capacitor C2. The first passivation layer 115a is an insulating layer which protects components below the first passivation layer 115a and may be configured by an inorganic material, such as silicon oxide SiOx or silicon nitride SiNx, but is not limited thereto.

The lower planarization layer 116 is disposed on the first passivation layer 115a. The lower planarization layer 116 may planarize an upper portion of the pixel circuit including the driving transistor DT. The lower planarization layer 116 may be configured by a single layer or a double layer, and for example, configured by benzocyclobutene or an acrylic-based organic material, but is not limited thereto.

Referring to FIGS. 4B and 5 together, a plurality of reflection plates RF are disposed on the lower planarization layer 116. The reflection plate RF is a configuration which reflects light emitted from the plurality of light emitting diodes 130 above the first substrate 110 and is formed with a shape corresponding to each of the plurality of sub pixels SP. One reflection plate RF may be disposed to cover the most area of one sub pixel SP. The reflection plate RF reflects the light emitted from the light emitting diode 130 and is also used as an electrode which electrically connects the light emitting diode 130 and the pixel circuit. Therefore, the reflection plate RF may include various conductive layers in consideration of a light reflection efficiency and a resistance. For example, the reflection plate RF may use an opaque conductive layer such as silver (Ag), aluminum (Al), molybdenum (Mo), titanium (Ti), or an alloy thereof and a transparent conductive layer such as indium tin oxide, but the structure of the reflection plate RF is not limited thereto.

The reflection plate RF includes a first reflection plate RF1 corresponding to the first sub pixel SP1, a second reflection plate RF2 corresponding to the second sub pixel SP2, a third reflection plate RF3 corresponding to the third sub pixel SP3, and a fourth reflection plate RF4 corresponding to the fourth sub pixel SP.

The first reflection plate RF1 includes a 1-1-th reflection plate RF1a overlapping most of the first sub pixel SP1 except for the red light emitting diode 130R in the first sub pixel SP1 and a 1-2-th reflection plate RF1b overlapping the red light emitting diode 130R of the first sub pixel SP1. The 1-1-th reflection plate RF1a may reflect light emitted from the red light emitting diode 130R above the red light emitting diode 130R. Further, the 1-1-th reflection plate RF1a may be electrically connected to the source electrode SE of the driving transistor DT and the second capacitor C2 of the first sub pixel SP1 through a first contact hole CH1 of the lower planarization layer 116 and the first passivation layer 115a. Therefore, the 1-1-th reflection plate RF1a may electrically connect the driving transistor DT and the first electrode 134 of the red light emitting diode 130R. The 1-2-th reflection plate RF1b reflects light emitted from the red light emitting diode 130R above the red light emitting diode 130R. Further, the 1-2-th reflection plate RF1b may serve as an electrode which electrically connects the second electrode 135 of the red light emitting diode 130R and the high potential power line VL1.

The second reflection plate RF2 includes a 2-1-th reflection plate RF2a overlapping most of the second sub pixel SP2 except for the red light emitting diode 130R included in the second sub pixel SP2 and a 2-2-th reflection plate RF2b overlapping the red light emitting diode 130R of the second sub pixel SP2. The 2-1-th reflection plate RF2a may reflect light emitted from the red light emitting diode 130R above the red light emitting diode 130R. The 2-1-th reflection plate RF2a is electrically connected to the source electrode SE of the driving transistor DT and the second capacitor C2 of the second sub pixel SP2 through the first contact hole CH1 to transmit a driving current from the driving transistor DT to the first electrode 134 of the red light emitting diode 130R in the second sub pixel SP2. Further, the 2-2-th reflection plate RF2b may be used as an electrode which reflects the light emitted from the red light emitting diode 130R above the red light emitting diode 130R and electrically connects the second electrode 135 of the red light emitting diode 130R to the high potential power line VL1.

The third reflection plate RF3 may be formed as one third reflection plate RF3 which overlaps the entire third sub pixel SP3. The third reflection plate RF3 may reflect light emitted from the green light emitting diode 130G of the third sub pixel SP3 above the green light emitting diode 130G. Further, the third reflection plate RF3 is electrically connected to the source electrode SE of the driving transistor DT and the second capacitor C2 of the third sub pixel SP3 through the first contact hole CH1 to transmit a driving current from the driving transistor DT to the first electrode 134 of the green light emitting diode 130G.

The fourth reflection plate RF4 may be formed as one fourth reflection plate RF4 which overlaps the entire fourth sub pixel SP. The fourth reflection plate RF4 reflects light emitted from the blue light emitting diode 130B of the fourth sub pixel SP above the blue light emitting diode 130B. Further, the fourth reflection plate RF4 is electrically connected to the source electrode SE of the driving transistor DT and the second capacitor C2 of the fourth sub pixel SP4 through the first contact hole CH1 to transmit a driving current from the driving transistor DT to the first electrode 134 of the blue light emitting diode 130B.

In the meantime, even though it has been described that the first sub pixel SP1 and the second sub pixel SP2 are formed with two reflection plates RF and the third sub pixel SP3 and the fourth sub pixel SP are formed with one reflection plate RF, the reflection plate RF may be designed in various manners. For example, only one reflection plate RF may be disposed in all the plurality of sub pixels SP, like the third sub pixel SP3 and the fourth sub pixel SP or a plurality of reflection plates RF may be disposed in all the sub pixels like the first sub pixel SP1 and the second sub pixel SP2, but the reflection plate is not limited thereto.

Further, it has been described that the red light emitting diode 130R of each of the first sub pixel SP1 and the second sub pixel SP2 is electrically connected to the high potential power line VL1 through the 1-2-th reflection plate RF1b and the 2-2-th reflection plate RF2b. However, all the red light emitting diode 130R, the green light emitting diode 130G, and the blue light emitting diode 130B may be separately connected to the high potential power line VL1 without the reflection plate RF, but are not limited thereto.

Referring to FIG. 5, the second passivation layer 115b is disposed on the plurality of reflection plates RF. The second passivation layer 115b is an insulating layer which protects components below the second passivation layer 115b and may be configured by a single layer or a double layer of silicon oxide SiOx or silicon nitride SiNx, but is not limited thereto.

An adhesive layer AD is disposed on the second passivation layer 115b. The adhesive layer AD is formed on the entire surface of the substrate 110 to fix or attach the light emitting diode 130 disposed on the adhesive layer AD. The adhesive layer AD may be formed of a photo curable adhesive material which is cured by light. For example, the adhesive layer AD may be formed of an acrylic-based material including a photoresist, but is not limited thereto. The adhesive layer AD may be formed on the entire surface of the first substrate 110 excluding a pad area in which the first pad electrode PAD1 is disposed.

The plurality of light emitting diodes 130 are disposed in each of the plurality of sub pixels SP on the adhesive layer AD. The light emitting diode 130 is an element which emits light by a current and includes a red light emitting diode 130R which emits red light, a green light emitting diode 130G which emits green light, and a blue light emitting diode 130B which emits blue light and implements light with various colors including white by a combination thereof. For example, the light emitting diode 130 may be a light emitting diode (LED) or a micro LED, but is not limited thereto.

One red light emitting diode 130R is disposed in each of the first sub pixel SP1 and the second sub pixel SP2, one pair of green light emitting diodes 130G is disposed in the third sub pixel SP3, and one pair of blue light emitting diodes 130B is disposed in the fourth sub pixel SP. That is, two red light emitting diodes 130R, two green light emitting diodes 130G, and two blue light emitting diodes 130B may be disposed in one pixel PX. At this time, each of the red light emitting diodes 130R are connected to the driving transistor DT of each of the first sub pixel SP1 and the second sub pixel SP2 to be individually driven. In contrast, one pair of green light emitting diodes 130G of the third sub pixel SP3 and one pair of blue light emitting diodes 130B of the fourth sub pixel SP are connected to one driving transistor DT in parallel to be driven.

The plurality of light emitting diodes 130 includes a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers doped with n type and p type impurities into a material such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium, and tin (Sn), but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN) or gallium nitride (GaN), but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 134 may be a cathode electrode. The first electrode 134 may be disposed on a top surface (e.g., an upper surface) of the first semiconductor layer 131 which is exposed from the emission layer 132 and the second semiconductor layer 133. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 may be disposed on the top surface (e.g., an upper surface) of the second semiconductor layer 133. The second electrode 135 is an electrode which electrically connects the high potential power line VL1 and the second semiconductor layer 133. In this case, the second semiconductor layer 133 is a semiconductor layer doped with a p-type impurity and the second electrode 134 may be an anode. The second electrode 135 may be configured by a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 136 which encloses the first semiconductor layer 131, the emission layer 132, the second semiconductor layer 133, the first electrode 134, and the second electrode 136 is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is formed to electrically connect a first connection electrode CE1 to the second electrode 135 and a second connection layer CE2 to the first electrode 134.

In the meantime, referring to FIG. 5, a part of the side surface of the first semiconductor layer 131 may be exposed from the encapsulation layer 136. That is, a part of the side surface of the first semiconductor layer 131 is non-overlapping with the encapsulation layer 136. For example, the encapsulation layer 136 may not be disposed on a lower side surface of the first semiconductor layer 131. The light emitting diode 130 manufactured on the wafer is separated from the wafer to be transferred onto the display panel PN. However, during the process of separating the light emitting diode 130 from the wafer, a part of the encapsulation layer 136 may be torn. For example, a part of the encapsulation layer 136 which is adjacent to a lower edge of the first semiconductor layer 131 of the light emitting diode 130 is torn during the process of separating the light emitting diode 130 from the wafer. Accordingly, a part of a lower side surface of the first semiconductor layer 131 may be exposed to the outside. However, the first planarization layer 117 to be described below is disposed to enclose the side surface or a lower portion of the light emitting diode 130 while being in contact with the exposed portion of the light emitting diode 130 that is non-overlapping with the encapsulation layer 136 such as the lower side surface of the first semiconductor layer 131. That is, even though the lower portion of the light emitting diode 130 is exposed from the encapsulation layer 136, the first planarization layer 117 is disposed to cover the lower portion of the light emitting diode 130. Therefore, even though the first connection electrode CE1 and the second connection electrode CE2 are formed thereafter, the first connection electrode CE1 and the second connection electrode CE2 and the first semiconductor layer 131 may not be in contact with each other due to the first planarization layer 117. Accordingly, the short problem may be reduced.

Next, the first planarization layer 117 and the second planarization layer 118 are disposed on the adhesive layer AD and the light emitting diode 130.

The first planarization layer 117 overlaps a part of side surfaces of the plurality of light emitting diodes 130 to fix and protect the plurality of light emitting diodes 130. The first planarization layer 117 may be formed using a halftone mask. Therefore, the first planarization layer 117 is formed to have a step.

The first planarization layer 117 includes a first open area OA1 and a second open area OA2. The first open area OA1 is an area having a height that is less (e.g., a lower height) than an adjacent area to form a step in the first planarization layer 117. That is, a first portion of the first planarization layer 117 that corresponds to the first open area OA1 has a first thickness that is less than a second thickness of a second portion of the first planarization layer 117 that extends from the first portion of the first planarization layer. Referring to FIGS. 4C and 5, the first open area OA1 is formed in an area overlapping the light emitting diode 130 or formed to enclose the light emitting diode 130 and has an area larger than that of the light emitting diode 130. Accordingly, a top surface of the light emitting diode 130 is exposed by the first open area OA1 and an upper portion of the side surface of the light emitting diode 130 is also exposed. In the first open area OA1, the lower side surface of the light emitting diode 130 is in contact with the first planarization layer 117. Referring to FIG. 5, a torn part of the encapsulation layer 136 which protects a side surface of the first semiconductor layer 131 of the light emitting diode 130 during the process of separating the light emitting diode 130 from the wafer to be transferred onto the display panel PN is covered by the first planarization layer 117. By doing this, contacts and short problems of the connection electrodes CE1 and CE2 and the first semiconductor layer 131 later may be suppressed.

An area adjacent to the first open area OA1 of the first planarization layer 117 has a thickness larger than that of the first open area OA1. That is, the first open area OA1 of the first planarization layer 117 which is relatively adjacent to the light emitting diode 130 is formed to have a smaller thickness and a part which is farther from the light emitting diode 130 is formed to have a larger thickness. That is, a top surface of an area adjacent to the first open area OA1 of the first planarization layer 117 is higher than a top surface of the first open area OA1 of the first planarization layer 117. Even though in FIG. 5, it is illustrated that the top surface of the area adjacent to the first open area OA1 of the first planarization layer 117 is located to be lower than the top surface of the light emitting diode 130, the top surface of the area adjacent to the first open area OA1 may be higher than the top surface of the light emitting diode 130. This may be adjusted depending on whether a coating material for forming the first planarization layer 117 is coated to cover the entire light emitting diode 130 during the process of forming the first planarization layer 117.

The second open area OA2 is an area from which the first planarization layer 117 is completely removed and is formed to correspond to a second contact hole CH2 for connecting the second connection electrode CE2 and the reflection plate RF. That is, the second open area OA2 may expose at least a part of the adhesive layer AD located there below. In other words, the second open area OA2 is through an entire thickness of the first planarization layer 117. The side surface of the first planarization layer 117 located in the second open area OA2 is in contact with the second connection electrode CE2 thereafter and the second open area OA2 may be filled with a bank BB.

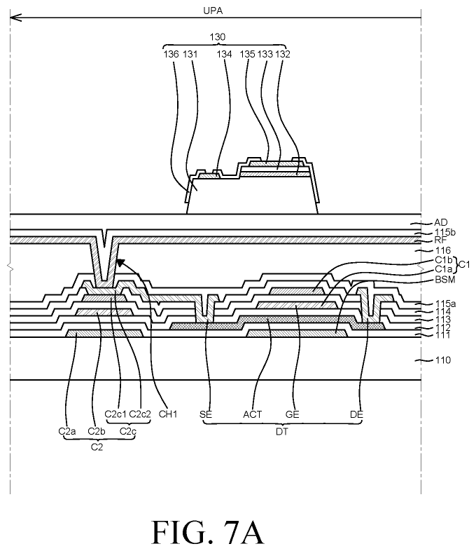

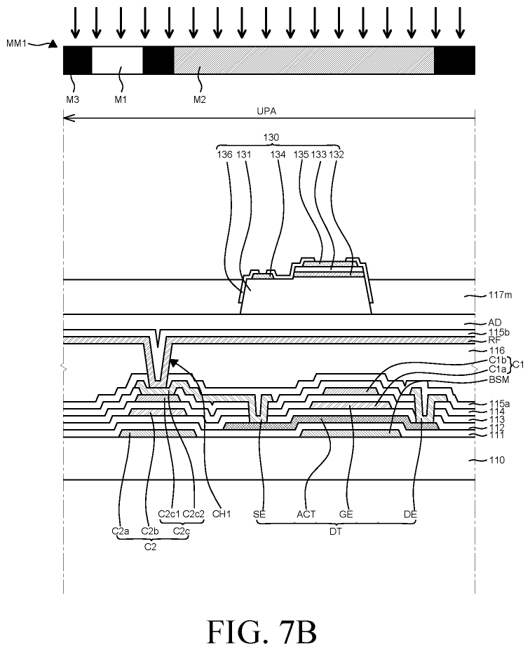

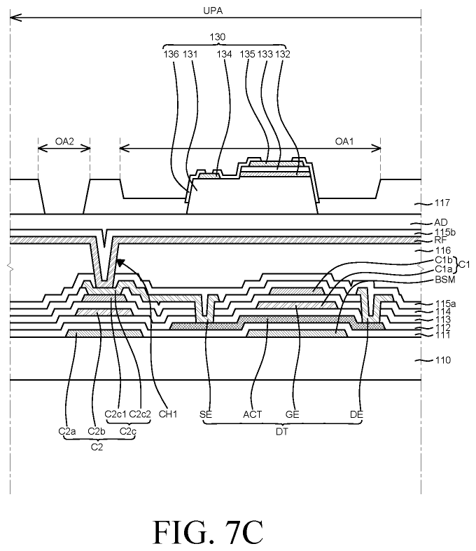

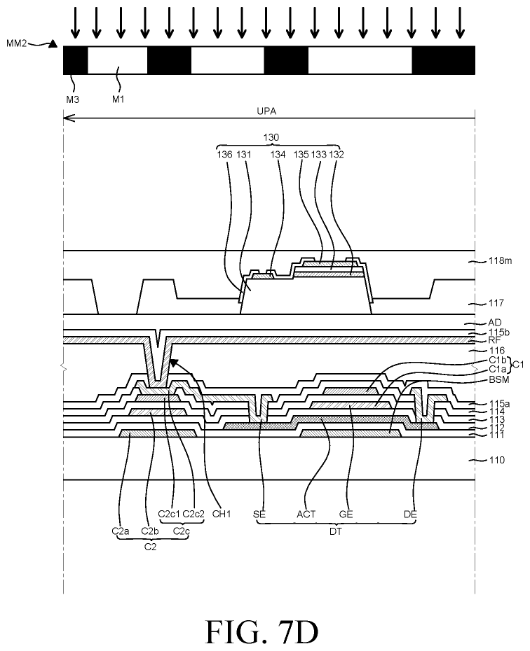

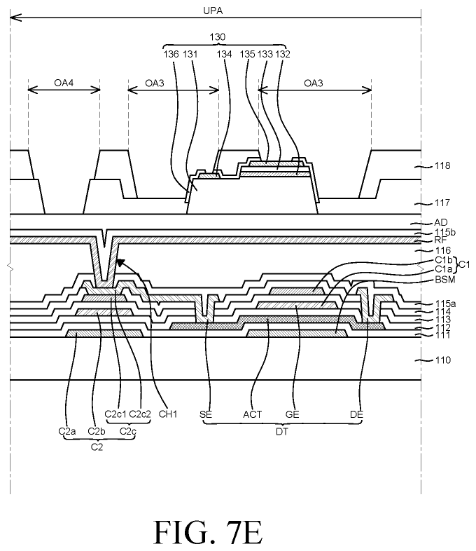

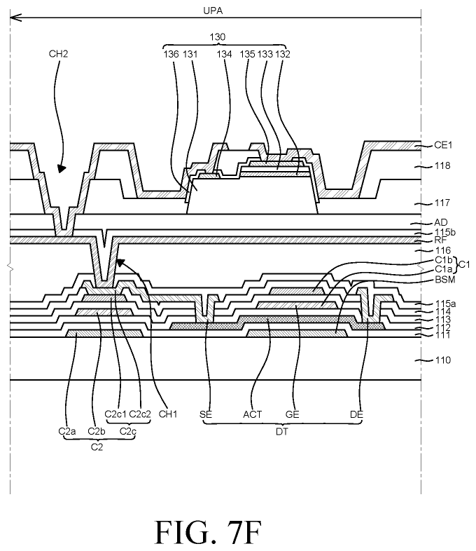

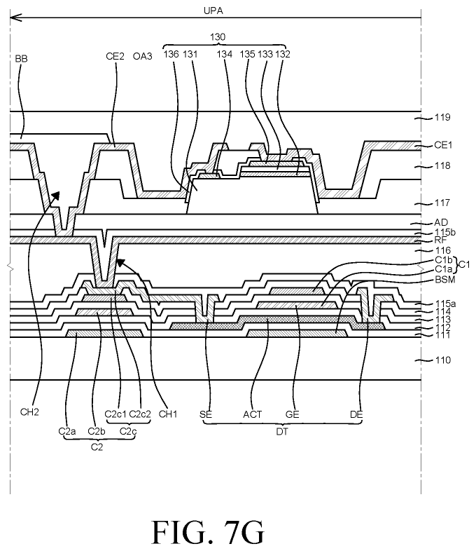

The first planarization layer 117 is formed by a photolithography. In this case, the first open area OA1 and the second open area OA2 may be simultaneously formed using a halftone mask. A process of forming the first planarization layer 117 will be described below with reference to FIGS. 7A to 7G.

The second planarization layer 118 is formed to cover a part of top surfaces of the first planarization layer 117 and the light emitting diode 130. The second planarization layer 118 includes a third open area OA3 and a fourth open area OA4.

The second planarization layer 118 includes a third open area OA3 which exposes at least a part of the first electrode 134 and the second electrode 135 of the light emitting diode 130. That is, the third open area OA2 overlaps at least a part of the first electrode 134 and the second electrode 135. Referring to FIGS. 4C and 5, a plurality of third open areas OA3 may be formed to expose the first electrode 134 and the second electrode 135, respectively. That is, the second planarization layer 118 is partially disposed between the first electrode 134 and the second electrode 135. In the meantime, the third open area OA3 may be formed in an area which does not overlap the first electrode 134 and the second electrode 135. For example, referring to FIG. 4C, the third open area OA3 includes a 3-1-th open area which is formed to at least partially overlap the first electrode 134 to open at least a part of the first electrode 134 and a 3-2-th open area which is spaced apart from the 3-1-th open area and does not overlap the first electrode 134. The 3-2-th open area may be a dummy open area which does not expose the first electrode 134. Even though in FIG. 4C, the 3-2-th open area does not overlap the first electrode 134, but may overlap the first electrode 134 depending on the size of the light emitting diode 130 or the size of the first electrode 134L. Further, when a transferring position of the light emitting diode 130 is deviated during the transferring process, that is, an alignment is deviated by a predetermined distance, a part of the 3-2-th open area may overlap the first electrode 134. In this case, the first electrode 134 may partially overlap the 3-1-th open area and the 3-2-th open area to be exposed or overlap only the 3-2-th open area to be exposed. That is, a plurality of third open areas OA3 is configured so that even though the light emitting diode 130 is misaligned, a contact between the first electrode 134 of the light emitting diode 130 and the first connection electrode CE1 may be formed.

A long axis direction of each third open area OA3 and a long axis direction of the first electrode 134 and the second electrode 135 may be formed to be different from each other. For example, referring to FIG. 4C, when the first electrode 134 has a shape which is elongated in a horizontal direction, the third open area OA3 may have a shape which is elongated in a vertical direction. In one embodiment, the long axis direction of the first electrode 134 is in a first direction (e.g., horizontal direction) and the long axis direction of the third open area OA3 is in a second direction (e.g., vertical direction) that is different from the first direction. For example, the long axis direction of the first electrode 134 and the long axis direction of the third open area OA3 may be perpendicular to each other. Accordingly, even though the misalignment is caused during the process of transferring the light emitting diode 130, an area of the first electrode 134 to be exposed may be sufficiently ensured.

The fourth open area OA4 is formed to correspond to a second contact hole CH2 for connecting the second connection electrode CE2 and the reflection plate RF. That is, the fourth open area OA2 overlaps the second open area OA2 of the first planarization layer 117 there below. The side surface of the second planarization layer 118 located in the fourth open area OA4 is in contact with the second connection electrode CE2 thereafter and the fourth open area OA4 may be filled with a bank BB.

The second planarization layer 118 is formed by a photolithography. In this case, the third open area OA3 and the fourth open area OA4 may be simultaneously formed using a full tone mask. A process of forming the second planarization layer 118 will be described below with reference to FIGS. 7A to 7G.

The first connection electrode CE1 and the second connection electrode CE2 are disposed on the second planarization layer 118. The first connection electrode CE1 is an electrode which electrically connects the second electrode 135 of the light emitting diode 130 and the high potential power line VL1. The first connection electrode CE1 may be electrically connected to the second electrode 135 of the light emitting diode 130 through the third open area OA3 formed in the second planarization layer 118.

The second connection electrode CE2 is an electrode which electrically connects the first electrode 134 of the light emitting diode 130 and the driving transistor DT. The second connection electrode CE2 is connected to the first electrode 134 of the light emitting diode 130 through the third open area OA3 formed in the second planarization layer 118. Further, the second connection electrode CE2 is connected to a 1-1-th reflection plate RF1a, a 2-1-th reflection plate RF2a, a third reflection plate RF3, and a fourth reflection plate RF4 of the plurality of sub pixels SP through the second open area OA2 formed in the first planarization layer 117, the third open area OA3 formed in the second planarization layer 118, and the second contact hole CH2 formed in the adhesive layer AD and the second passivation layer 115b. At this time, the 1-1-th reflection plate RF1a, the 2-1-th reflection plate RF2a, the third reflection plate RF3, and the fourth reflection plate RF4 are also connected to the source electrode SE of the driving transistor DT so that the source electrode SE of the driving transistor DT and the first electrode 134 of the light emitting diode 130 may be electrically connected to each other.

In the meantime, in the drawing, it is illustrated that the first electrode 134, the second connection electrode CE2, and the reflection plate RF are electrically connected to the source electrode SE of the driving transistor DT. However, the first electrode 134, the second connection electrode CE2, and the reflection plate RF may be connected to the drain electrode DE of the driving transistor DT, but it is not limited thereto.

The bank BB is disposed on the first connection electrode CE1, the second connection electrode CE2, and the second planarization layer 118. The bank BB may be disposed to be spaced apart from the light emitting diode 130 with a predetermined interval and at least partially overlaps the reflection plate RF. For example, the bank BB may cover a part of the second connection electrode CE2 formed in the second contact hole CH2 of the second planarization layer 118 and the first planarization layer 117.

Even though it is illustrated in FIG. 5 that the second planarization layer 118 is disposed on both sides of the first open area OA of the first planarization layer 117, the second planarization layer 118 may also be disposed on only one side of the first open area OA1. For example, the second planarization layer 118 is disposed on a left side of the first open area OA1 adjacent to the second open area OA2 with respect to the light emitting diode 130 and not the second planarization 118, but the bank BB may be disposed on the right side of the first open area OA1. In this case, the bank BB may be disposed on the first planarization layer 117 with a predetermined interval from the light emitting diode 130. At this time, the bank BB and the second planarization layer 118 may be spaced apart from each other on the first open area OA1 of the first planarization layer 117 with a smaller thickness. That is, an end of the bank BB and an end of the second planarization layer 118 may be disposed on the first open area OA1 of the first planarization layer 117 having a smaller thickness formed by a halftone mask process to be spaced apart from each other.

In the meantime, a thickness of a part of the bank BB which is formed in the second contact hole CH2 of the second planarization layer 118 and the first planarization layer 117 to cover a part of the second connection electrode CE2 and a thickness of a part disposed on the second planarization layer 118 may be different from each other. Specifically, when the part of the bank BB covers a part of the second connection electrode CE2 formed in the second contact hole CH2 of the second planarization layer 118 and the first planarization layer 117, since the second contact hole CH2 is formed from the second passivation layer 115b to the second planarization layer 118, the bank BB may be disposed below the light emitting diode 130, that is, disposed to be lower than the light emitting diode 130. Therefore, the thickness of the part of the bank BB which covers a part of the second connection electrode CE2 formed in the second contact hole CH2 of the second planarization layer 118 and the first planarization layer 117 may be larger than the thickness of a part of the bank BB disposed on the first planarization layer 117.

The bank BB may be formed of an opaque material to reduce color mixture between the plurality of sub pixels SP and for example, may be formed of black resin, but is not limited thereto.

A first protection layer 119 is disposed on the first connection electrode CE1, the second connection electrode CE2, and the bank BB. The first protection layer 119 is a layer which protects components below the first protection layer 119. The first protection layer 119 may be configured by a single layer or a double layer, and for example, configured by benzocyclobutene, a light-transmitting epoxy, a photoresist, or an acrylic-based organic material, but is not limited thereto.

A plurality of first pad electrodes PAD1 are disposed in a first pad area PA1 and a second pad area PA2 of the first substrate 110. Each of the plurality of first pad electrodes PAD1 may be configured by a plurality of conductive layers. For example, each of the plurality of first pad electrodes PAD1 includes a first conductive layer PE1a, a second conductive layer PE1b, and a third conductive layer PE1c.

First, the first conductive layer PE1a is disposed on the second interlayer insulating layer 114. The first conductive layer PE1a is formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The first passivation layer 115a is disposed on the first conductive layer PE1a and the second conductive layer PE1b is disposed on the first passivation layer 115a. The second conductive layer PE1b is formed of the same conductive material as the reflection plate RF and for example, may be configured by silver (Ag), aluminum (Al), molybdenum (Mo), or an alloy thereof, but is not limited thereto.

The third conductive layer PE1c is disposed on the second conductive layer PE1b. The third conductive layer PE1c is formed of the same conductive material as the first connection electrode CE1 and the second connection electrode CE2, and for example, a transparent conductive material, such as indium tin oxide (ITO) or indium zinc oxide (IZO), but is not limited thereto.

At this time, even though it is not illustrated in the drawings, a part of the plurality of conductive layers of the first pad electrode PAD1 are electrically connected to a plurality of wiring lines on the first substrate 110 to supply various signals to a plurality of wiring lines and a plurality of sub pixels SP. For example, the first conductive layer PE1a and/or the second conductive layer PE1b of the first pad electrode PAD1 is connected to the data line DL, the high potential power line VL1, and the low potential power line VL2 disposed in the active area AA to transmit signals thereto.

Further, a first metal layer ML1, a second metal layer ML2, and a plurality of insulating layers may be disposed below the first pad electrode PAD1. The first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. The first metal layer ML1 is formed of the same conductive material as the gate electrode GE and the second metal layer ML2 may be formed of the same conductive material as a 1-2-th capacitor electrode C1b. However, the plurality of insulating layers, the first metal layer ML1, and the second metal layer ML2 below the first pad electrode PAD1 may be omitted depending on a design and are not limited thereto.

A second substrate 120 is disposed below the first substrate 110. The second substrate 120 is a substrate which supports components disposed below the display device 100 and may be an insulating substrate. For example, the second substrate 120 may be formed of glass or resin. Further, the second substrate 120 may include polymer or plastic. The second substrate 120 may be formed of the same material as the first substrate 110. In some exemplary embodiments, the second substrate 120 may be formed of a plastic material having flexibility.

A bonding layer BDL is disposed between the first substrate 110 and the second substrate 120. The bonding layer BDL may be formed of a material which is cured by various curing methods to bond the first substrate 110 and the second substrate 120. The bonding layer BDL may be disposed only in a partial area between the first substrate 110 and the second substrate 120 or is disposed in the entire area.

A plurality of second pad electrodes PAD2 are disposed on a rear surface of the second substrate 120. The plurality of second pad electrodes PAD2 are electrodes which transmit a signal from a driving component disposed on the rear surface of the second substrate 120 to a plurality of side lines SRL and a plurality of first pad electrodes PAD1 and a plurality of wiring lines on the first substrate 110. The plurality of second pad electrodes PAD2 is disposed in an end portion of the second substrate 120 in the non-active area NA to be electrically connected to the side line SRL which covers the end portion of the second substrate 120.

At this time, the plurality of second pad electrodes PAD2 may be also disposed so as to correspond to the plurality of pad areas. The plurality of first pad electrodes PAD1 may be disposed to correspond to the plurality of second pad electrodes PAD2, respectively, and then the first pad electrode PAD1 and the second pad electrode PAD2 which overlap each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed below the second substrate 120. The fourth conductive layer PE2a may be configured by a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b may be configured by a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c is formed of a conductive material, for example, a transparent conductive material, such as indium tin oxide (ITO) or indium zinc oxide (IZO), but is not limited thereto.

Further, the second protection layer 121 is disposed in the remaining area of the second substrate 120. The second protection layer 121 may protect various wiring lines and driving components formed on the second substrate 120. The second protection layer 121 may be configured by a single layer or a double layer, and for example, configured by benzocyclobutene, a light-transmitting epoxy, a photoresist, or an acrylic-based organic insulating material, but is not limited thereto.

In the meantime, even though it is not illustrated in the drawing, a driving component including a plurality of flexible films and a printed circuit board may be disposed on a rear surface of the second substrate 120. The plurality of flexible films is components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC may be disposed.

For example, the fourth conductive layer PE2a and/or the fifth conductive layer PE2b of the second pad PAD2 extend to the plurality of flexible films disposed on the rear surface of the second substrate 120 to be electrically connected to the plurality of flexible films. The plurality of flexible films may supply various signals to the plurality of side lines SRL, the plurality of first pad electrodes PAD1, the plurality of wiring lines, and the plurality of sub pixels SP through the second pad electrode PAD2. Therefore, the signal from the driving component is transmitted to the signal line and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL are disposed on the side surfaces of the first substrate 110 and the second substrate 120. The plurality of side lines SRL may electrically connect the plurality of first pad electrodes PAD1 formed on the top surface of the first substrate 110 and the plurality of second pad electrodes PAD2 formed on the rear surface of the second substrate 120. The plurality of side lines SRL may be disposed so as to enclose the side surface of the display device 100. Each of the plurality of side lines SRL may cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL is formed by a pad printing method using a conductive ink including silver (Ag), copper (Cu), molybdenum (Mo), and chrome (Cr).

A side insulating layer 140 which covers the plurality of side lines SRL is disposed. The side insulating layer 140 may be formed on the top surface of the first substrate 110, the side surface of the first substrate 110, the side surface of the second substrate 120, and the rear surface of the second substrate 120 to cover the side line SRL. The side insulating layer 140 may protect the plurality of side lines SRL.

In the meantime, when the plurality of side lines SRL are formed of a metal material, there may be a problem in that external light is reflected from the plurality of side lines SRL or light emitted from the light emitting diode 130 is reflected from the plurality of side lines SRL to be visibly recognized by the user. Therefore, the side insulating layer 140 is configured to include a black material to suppress reflection of the external light. For example, the side insulating layer 140 may be formed by a pad printing method using an insulating material including a black material, for example, a black ink.

A seal member 150 which covers the side insulating layer 140 is disposed. The seal member 150 is disposed so as to enclose the side surface of the display device 100 to protect the display device 100 from external impacts, moisture, and oxygen. For example, the seal member 150 may be formed of polyimide (PI), poly urethane, epoxy, or acryl-based insulating material, but is not limited thereto.

An optical film MF is disposed on the seal member 150, the side insulating layer 140, and the first protection layer 119. The optical film MF may be a functional film which implements a higher quality of images while protecting the display device 100. For example, the optical film MF may be an anti-scattering film, an anti-glare film, an anti-reflecting film, a low-reflecting film, an Oled transmittance controllable film, or a polarizer, but is not limited thereto.

In the meantime, an edge of the seal member 150 and an edge of the optical film MF may be disposed on the same line. The optical film ML having a larger size is attached above the first substrate 110 during the manufacturing process of the display device 100 and the seal member 150 which covers the side insulating layer 140 may be formed. Thereafter, laser is irradiated on the seal member 150 and the optical film MF so as to correspond to an edge of the display device 100 to cut a part of the seal member 150 and the optical film MF. Accordingly, the size of the display device is adjusted by an outer periphery cutting process of the seal member 150 and the optical film MF and the edge of the display device 100 may be formed to be flat.

The display device according to the exemplary embodiment of the present disclosure has a structure in which dual planarization layers 117 and 118 are formed in the vicinity of the light emitting diode 130 transferred onto the display panel PN. With this structure, electrodes 134 and 135 of the light emitting diode 130 are in stably contact with the connection electrodes CE1 and CE2. Further, even when the transferring position is deviated or misaligned during the process of transferring the light emitting diode 130, the electrodes 134 and 135 of the light emitting diode 130 and the connection electrodes CE1 and CE2 are in easily contact with each other. Further, when the light emitting diode 130 is misaligned, the short caused by the contact between the semiconductor layer 131 exposed on the lower side surface of the light emitting diode 130 and the connection electrodes CE1 and CE2 may be suppressed.

As compared with the display device according to the exemplary embodiment of the present disclosure, when the planarization layer for fixing and protecting the light emitting diode is configured by a single layer, the photolithographic process needs to be performed after coating a much larger thickness than the thickness of the light emitting diode to form the single planarization layer to form a contact hole for exposing the electrode of the light emitting diode. A lot of residuals is generated during this problem, which makes it difficult to form the contact hole. Further, when the transferring position is deviated or misalignment is caused during the process of transferring the light emitting diode before forming the planarization layer, there is a problem in that the contact hole does not overlap the electrode of the light emitting diode.

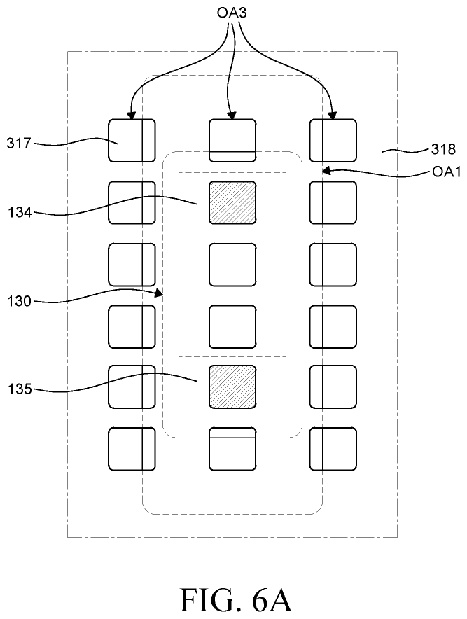

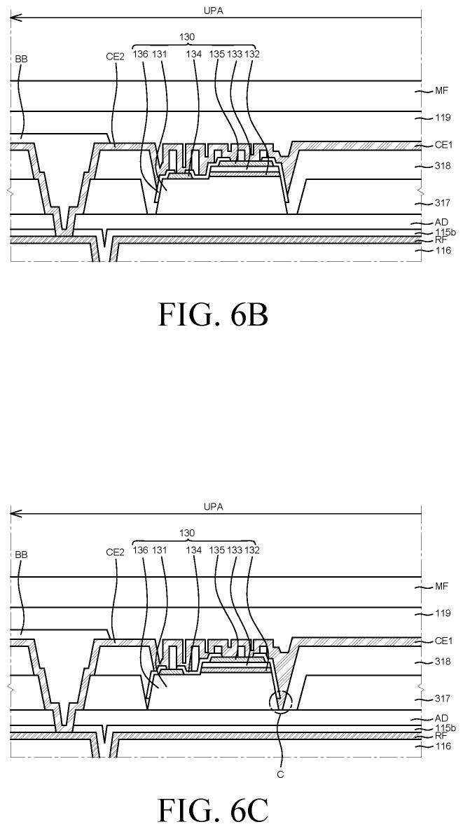

Therefore, a structure which configures a dual planarization layer after transferring the light emitting diode has been introduced. A display device according to a comparative embodiment to which a double-layered planarization layer of the related art is applied will be described with reference to FIGS. 6A to 6C.

FIGS. 6A and 6B are views for explaining a display device according to a comparative embodiment. FIG. 6A is a schematic plan view for explaining a light emitting diode of one sub pixel and a planarization layer to explain a display device according to a comparative embodiment. FIG. 6C illustrates a structure in which a light emitting diode is misaligned when a display device according to a comparative embodiment of FIGS. 6A and 6B is manufactured.

First, referring to FIGS. 6A and 6B, a first planarization layer 317 and a second planarization layer 318 are disposed on the adhesive layer AD and the light emitting diode 130.

At this time, the first planarization layer 317 includes a first open area OA1 which is larger than the light emitting diode and is completely removed to expose an adhesive layer there below. As described above, in order to solve the problem of the residual film generated by using the single layer of planarization layer and a problem caused by the misalignment of the light emitting diode, the first open area OA1 which is larger than the light emitting diode is formed so that the light emitting diode 130 and the side surface of the first planarization layer 317 are spaced apart from each other.

Thereafter, the second planarization layer 318 is formed on the first planarization layer 317. At this time, the second planarization layer 318 forms a plurality of third open areas OA3 which exposes the first planarization layer 317 and the light emitting diode 130. The third open area OA3 is provided to form a contact hole which exposes the first electrode 134 and the second electrode 135 of the light emitting diode 130. Therefore, when the transferring position is deviated or the misalignment is generated during the process of transferring the light emitting diode 130, the electrodes 134 and 135 and the third open area OA3 do not overlap so that the contact hole is not properly formed. Therefore, in order to suppress this problem, the plurality of third open areas with small sizes is formed. That is, as illustrated in FIG. 6B, even though the position of the light emitting diode 130 moves, some of the plurality of third open areas OA3 overlaps the first electrode 134 and the second electrode 135 of the light emitting diode 130 to form a contact hole.

However, as illustrated in FIG. 6C, when the light emitting diode 130 is misaligned, a lower side surface of the light emitting diode may be exposed from an overlapping portion of the first open area OA1 of the first planarization layer 317 and the third open area OA3 of the second planarization layer 318B. Specifically, when the light emitting diode is misaligned to move to the left side from a designed position, an adhesive layer AD which is exposed by the first open area OA1 of the first planarization layer 317 located at a right side of the light emitting diode is increased. That is, a space between a right side surface of the light emitting diode 130 and a side surface of the first planarization layer 317 may be increased. Thereafter, when the third open area OA3 of the second planarization layer 318 overlaps an upper portion of the increased space, the lower side surface of the light emitting diode 130 is exposed. At this time, the first semiconductor layer 131 of the exposed light emitting diode 130 and connection electrodes CE1 and CE2 which are deposited thereafter are in contact (C) with each other to cause the short problem. In order to solve this problem, a method of configuring the size of the third open area OA3 of the second planarization layer 318 to be smaller and increasing the number of the third open areas has been considered. However, the contact area through which the first electrode 134 and the second electrode 135 of the light emitting diode 130 is reduced and it is difficult to form the interval between the third open areas OA3 to be sufficiently small so that there is a problem in the process.

Accordingly, in the display device according to the exemplary embodiment of the present disclosure, the first planarization layer 117 with a step is disposed using a halftone mask. As illustrated in FIG. 5, a first open area OA1 is formed by partially removing a portion of the first planarization layer 117 while being in contact with the side surface of the light emitting diode 130 to fix the light emitting diode 130 and protect the lower side surface and the edge of the light emitting diode 130. Thereafter, the exposure of the lower surface of the light emitting diode 130 when the third open area OA3 of the second planarization layer 118 is formed may be suppressed. The first planarization layer 117 which forms the first open area OA1 using the halftone may minimize or reduce the residual film during the process and the size of the third open area OA3 of the second planarization layer 118 is formed to be larger so that the contact area of the first electrode 134 and the second electrode 135 of the light emitting diode 130 may be increased. In one embodiment, the contact area of the first electrode 134 is different than the contact area of the second electrode 135 due to the area of the first electrode 134 that is non-overlapped by the encapsulation layer 136 in the third open area OA3 being different from the area of the second electrode 135 that is non-overlapped by the encapsulation layer 136 in the third open area OA3.

Hereinafter, a method for forming a first planarization layer and a second planarization layer after transferring the light emitting diode onto the display panel will be described with reference to FIGS. 7A to 7F.

FIGS. 7A to 7F are schematic cross-sectional views for explaining a manufacturing method of a display device according to an exemplary embodiment of the present disclosure.

First, referring to FIG. 7A, the light emitting diode 130 is transferred onto the display panel PN. Specifically, a first substrate 110 on which a plurality of pixel circuits, a lower planarization layer 116, a reflection plate RF, and a second passivation layer 115b are formed is prepared and an adhesive layer AD is disposed. Thereafter, the light emitting diode 130 is transferred onto the adhesive layer AD. The display panel PN and a donor are aligned using an alignment key formed in an area between the plurality of pixel areas UPA and the plurality of light emitting diodes 130 of the donor may be transferred onto the display panel PN.

Referring to FIG. 7B, a first photoresist layer 117m is formed on the light emitting diode 130 and the adhesive layer AD. The first photoresist layer 117m may be formed of a positive photoresist, but is not limited thereto. The positive photoresist is a photoresist whose solubility of the exposed portion in the developer is increased by the exposure. When the positive photoresist is developed, a pattern from which exposed portions are removed is obtained.

In FIG. 7B, a structure in which the first photoresist layer 117m is formed to expose a top surface of the light emitting diode 130 and a height of the first photoresist layer 117m is smaller than a height of the light emitting diode 130 is illustrated, but is not limited thereto. The height of the first photoresist layer 117m may vary in various heights depending on a maximum height and a design structure of the first planarization layer 117 and the first photoresist layer 117m may be disposed to cover all the light emitting diodes 130.

After disposing a first mask MM1 on the first photoresist layer 117m, an exposure process which is a photolithographic process is performed. At this time, the first mask MM1 is a halftone mask and is configured by masks having different light transmission amounts. That is, the first mask MM1 is configured by a transmissive area M1, a blocking area M2, and a semi-transmissive area M3. The first photoresist layer 117m corresponding to the transmissive area M1 is removed by a subsequent development process to form a second open area OA2 and the first photoresist layer 117m corresponding to the semi-transmissive area M3 is removed by the subsequent development process to form the first open area OA1. The first photoresist layer 117m corresponding to the blocking area M2 is maintained without being removed by the subsequent development process to form a step with the first open area OA1. Accordingly, the transmissive area M1 of the first mask MM1 is disposed so as to overlap an edge of the second open area OA2 and the semi-transmissive area M3 is disposed so as to overlap an edge of the first open area OA1.

Next, referring to FIG. 7C, the first photoresist layer 117b which has undergone the exposure process is reacted with a developer to remove the first photoresist layer 117m in the exposed area. Next, a baking process which is a heating process is performed so that the first photoresist layer 117m corresponding to the transmissive area M1 reacts with the developer to be removed in the exposure process to form the second open area OA2. In the second open area OA2, all the first photoresist layer 117m is substantially removed to expose the adhesive layer AD there below. The first photoresist layer 117m corresponding to the blocking area M2 does not react with the developer to form a tapered first planarization layer 117. The first photoresist layer 117m corresponding to the semi-transmissive area M3 is partially removed to form the first open area OA1 having a height (e.g., thickness) lower than the height of the light emitting diode 130. Accordingly, the first planarization layer 117 including the first open area OA1, the second open area OA2, and a remaining area which is not removed is formed.

Next, referring to FIG. 7D, the second photoresist layer 118m is formed on the first planarization layer 117. The second photoresist layer 118m is formed of the same material as the first photoresist layer 117m and is formed of a positive photoresist, but is not limited thereto. The second photoresist layer 118m is formed to cover the entire top surface of the light emitting diode 130. By doing this, the second planarization layer 118 may be formed between the first electrode 134 and the second electrode 135 so as not to cause the short of the first electrode 134 and the second electrode 135 of the light emitting diode 130.

After disposing the second mask MM2 on the second photoresist layer 118m, an exposure process which is a photolithographic process is performed. The second mask MM2 is configured by a transmissive area M1 and a blocking area M2. The second photoresist layer 118m corresponding to the transmissive layer M1 is removed by the subsequent development process to form a third open area OA3 and a fourth open area OA4. Specifically, an area of the transmissive area M1 which overlaps the light emitting diode 130 forms the third open area OA3 through which the first electrode 134 and the second electrode 135 of the light emitting diode 130 are exposed thereafter. An area of the transmissive area M1 which overlaps the second open area OA2 of the first planarization layer 117 forms the fourth open area OA4 through which the second connection electrode CE2 and the reflection plate RF are in contact with each other thereafter.

Next, referring to FIG. 7E, the second photoresist layer 118m which has undergone the exposure process is reacted with a developer to remove the second photoresist layer 118m in the exposed area. Next, a baking process which is a heating process is performed so that the second photoresist layer 118m corresponding to the transmissive area M2 reacts with the developer to be removed in the exposure process to form the third open area OA3 and the fourth open area OA4. In the third open area OA3, all the second photoresist layer 118m is substantially removed to expose the first planarization layer 117 there below and in the third open area OA3, all the second photoresist layer is substantially removed and overlaps the second open area OA2 of the first planarization layer 117 to expose the adhesive layer AD there below. The second photoresist layer 118m corresponding to the blocking area M2 does not react with the developer and forms a tapered second planarization layer 118. The second planarization layer 118 is disposed on the first planarization layer 117 and is disposed between the first electrode 134 and the second electrode 135 of the light emitting diode 130.

Next, referring to FIG. 7F, the second contact hole CH2 is formed in the second passivation layer 115b and the adhesive layer AD so as to correspond to the second open area OA2 of the first planarization layer 117 and the third open area OA3 of the second planarization layer 118 to expose a part of the reflection plate RF located there below.

Thereafter, the first connection electrode CE1 and the second connection electrode CE2 are formed on the second planarization layer 118. The first connection electrode CE1 is electrically connected to the second electrode 135 exposed through the third open area OA3 and the second connection electrode CE2 is electrically connected to the first electrode 134 exposed through the third open area OA3. In the meantime, the second connection electrode CE2 is electrically connected to the reflection plate RF which is disposed in the second contact hole CH2 corresponding to the second open area OA2 of the first planarization layer 117 and the third open area OA3 of the second planarization layer 118 to be exposed there below.

Next, referring to FIG. 7G, the bank BB is disposed so as to correspond to the second open area OA2 and the fourth open area OA4. Further, the bank BB may be disposed on the second planarization layer 118 to be spaced apart from the light emitting diode 130. Thereafter, a first protection layer 119 is disposed on the first connection electrode CE1, the second connection electrode CE2, and the bank BB. The first protection layer 119 planarizes upper portions of the first connection electrode CE1, the second connection electrode CE2, and the bank BB. Accordingly, a display panel PN in which the light emitting diode 130 is transferred onto the first substrate 110 may be formed.

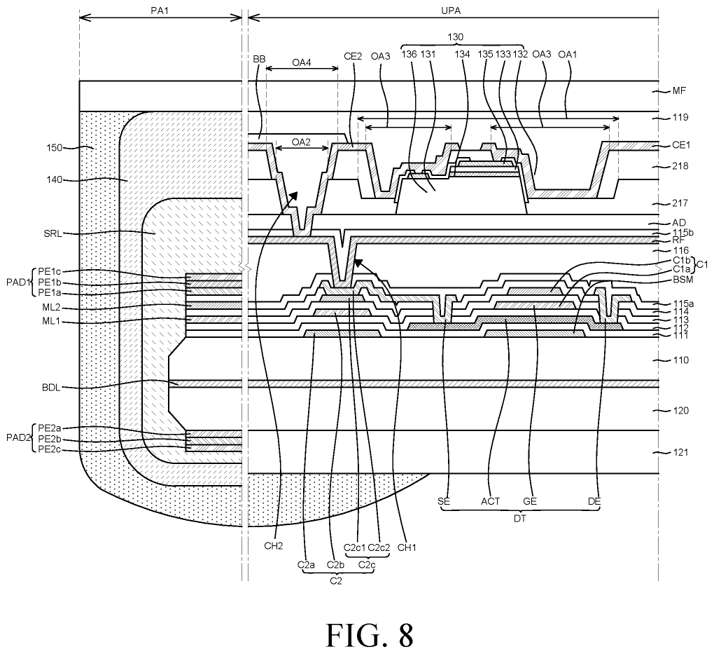

FIG. 8 is a cross-sectional view of a display device according to another exemplary embodiment of the present disclosure. A display device illustrated in FIG. 8 is substantially the same as the display device illustrated in FIG. 5 except that the position of the light emitting diode 130 is changed so that shapes of a first planarization layer 217 and a second planarization layer 218 adjacent thereto are changed. Therefore, a description of repeated components will be omitted.

As compared with the display device illustrated in FIG. 5, the light emitting diode 130 is disposed to move to a left side in the display device illustrated in FIG. 8. Generally, a transferring position is deviated or misalignment is generated during the process of transferring the light emitting diode 130. In this case, the light emitting diode 130 may be disposed in a position which is different from an initially intended position. In FIG. 8, the light emitting diode is disposed to move to the left side from an initially designed position.

Referring to FIG. 8, the light emitting diode 130 is disposed in the first open area OA1 of the first planarization layer 217 and a side surface of the light emitting diode 130 is in contact with a side surface of the first planarization layer 217 located in the first open area OA1. As described in FIG. 7B, after transferring the light emitting diode 130 onto the display panel PN, the first photoresist layer 117m is entirely coated and then the photolithographic process is performed using a halftone mask to form the first open area OA1. Therefore, even though the light emitting diode 130 is misaligned, the side surface of the first planarization layer 217 may be in contact with the light emitting diode 130.

As the light emitting diode 130 moves to the left side, the second planarization layer 218 located above the light emitting diode 130 is biased to the right side to overlap a part of the second electrode 135. Thus, the amount of overlap between the second planarization layer 218 and the second electrode 135 in FIG. 8 is more than the amount of overlap between the planarization layer 218 and the second electrode 135 in FIG. 5. Even though a contact area through which the second electrode 135 is exposed is reduced, sufficient exposed area can be ensured in the event of the misalignment of the light emitting diode 130, which allows it to make contact with the connection electrode thereafter.

Unlike the display device according to the comparative embodiment which has been described with reference to FIGS. 6A to 6C, in the display device illustrated in FIG. 8, even though the light emitting diode 130 is misaligned, the side surface of the light emitting diode 130 is still protected by the first planarization layer 217. Therefore, the contact problem of the connection electrode CE1 which is deposited thereafter by exposing the lower side surface of the light emitting diode 130 with the semiconductor layer 131 of the light emitting diode 130 through the third open area OA3 of the second planarization layer 118 is not caused.

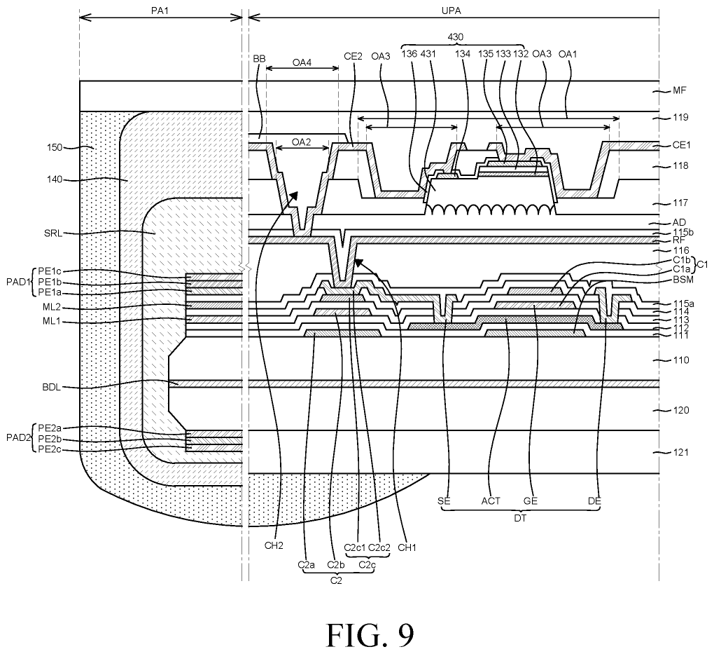

FIG. 9 is a cross-sectional view for explaining a display device according to still another exemplary embodiment of the present disclosure. A display device illustrated in FIG. 9 is substantially the same as the display device illustrated in FIG. 5 except that a shape of a bottom surface of a first semiconductor layer 431 of a light emitting diode 430 is changed. Therefore, a description of repeated components will be omitted.

Referring to FIG. 9, a plurality of patterns are formed on a bottom surface of the first semiconductor layer 431 of the light emitting diode 430. A pattern including a plurality of convex portions and a plurality of concave portions is formed on a bottom surface of the first semiconductor layer 431. The plurality of patterns increase a total reflectance when light emitted from the light emitting diode 430 is downwardly emitted to increase a light emission efficiency. Further, the plurality of patterns refracts light upwardly reflected by the reflection plate RF disposed below the light emitting diode 430 to improve an emitted light quantity to increase the light emission efficiency.

The exemplary embodiments of the present disclosure can also be described as follows:

According to an aspect of the present disclosure, there is provided a display device. The display device comprises a display panel in which a plurality of sub pixels is defined; a light emitting diode which is disposed in each of the plurality of sub pixels; a first planarization layer which is disposed on the display panel and encloses the light emitting diode; a second planarization layer disposed on the first planarization layer and the light emitting diode; and a connection electrode disposed on the second planarization layer. The first planarization layer has a height smaller than that of another adjacent area and includes a first open area which encloses the light emitting diode.

The first open area overlaps the light emitting diode in plan view and may have a larger area than that of the light emitting diode.

The first planarization layer may be in contact with a side surface of the light emitting diode in the first open area.

The first planarization layer may be formed by photolithography using a halftone mask.

The light emitting diode may include a first semiconductor layer on the display panel; a second semiconductor layer disposed on the first semiconductor layer; an emission layer disposed between the first semiconductor layer and the second semiconductor layer; a first electrode which is disposed on the first semiconductor layer and is spaced apart from the emission layer; a second electrode disposed on the second semiconductor layer; and an encapsulation layer which encloses at least a part of the first semiconductor layer, the emission layer, the second semiconductor layer, the first electrode, and the second electrode.

At least a part of the side surface of the first semiconductor layer may be exposed from the encapsulation layer to the outside and in the first open area, the first planarization layer may be in contact with a side surface of the semiconductor layer exposed from the encapsulation layer to the outside.

The first planarization layer may further include a second open area whose portion is completely removed to bring a reflection plate connected to a pixel circuit of the display panel into contact with the connection electrode.

The second planarization layer may include a plurality of third open areas which exposes the first electrode and the second electrode.

The third open area may be located in the first open area and the connection electrode may be in contact with the first planarization layer exposed by the third open area.

The second planarization layer may further include a dummy open area which does not overlap the first electrode and the second electrode.

A long axis direction of the plurality of third open areas and a long axis direction of the first electrode and the second electrode may be perpendicular to each other.

An area of the first electrode exposed by the third open area may be different from an area of the second electrode exposed by the third open area.

The second planarization layer may further include a fourth open area whose portion is completely removed to bring a reflection plate connected to a pixel circuit of the display panel into contact with the connection electrode.

A bottom surface of the first semiconductor layer may include a pattern unit including a plurality of convex portions and a plurality of concave portions.

The display panel may include an active area in which the plurality of sub pixels is disposed and a non-active area which encloses the active area, and the active area may further include a plurality of gate driving areas which extends from the plurality of sub pixels and includes a gate driver disposed therein.

Active layers of a plurality of transistors disposed in the plurality of sub pixels and active layers of a plurality of transistors disposed in the gate driver may be formed by oxide semiconductor, amorphous silicon, or polysilicon.

The plurality of transistors disposed in the gate driver may include active layers formed of different materials.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display panel including a plurality of subpixels;
a light emitting diode in a subpixel from the plurality of subpixels;
a first planarization layer that encloses the light emitting diode;
a second planarization layer on the first planarization layer and the light emitting diode; and
a connection electrode on the second planarization layer, the connection electrode connected to the light emitting diode,
wherein the first planarization layer includes a first open area that encloses the light emitting diode and a portion of the first planarization layer corresponding to the first open area has a first thickness that is less than a second thickness of a second portion of the first planarization layer.

2. The display device according to claim 1, wherein the first open area overlaps the light emitting diode in a plan view of the display device and the first open area has an area that is larger than an area of the light emitting diode.

3. The display device according to claim 2, wherein the first planarization layer is in direct contact with a side surface of the light emitting diode in the first open area.

4. The display device according to claim 3, wherein the first planarization layer is formed by photolithography using a halftone mask.

5. The display device according to claim 1, wherein the light emitting diode includes:
a first semiconductor layer on the display panel;
a second semiconductor layer on the first semiconductor layer;
an emission layer between the first semiconductor layer and the second semiconductor layer;
a first electrode on the first semiconductor layer and is spaced apart from the emission layer;
a second electrode on the second semiconductor layer; and
an encapsulation layer that encloses a first part of a side surface of the first semiconductor layer, the emission layer, the second semiconductor layer, the first electrode, and the second electrode.

6. The display device according to claim 5, wherein a second part of the side surface of the first semiconductor layer is non-overlapping with the encapsulation layer in the first open area and the first planarization layer is in contact with the second part of the side surface that is non-overlapping with the encapsulation layer.

7. The display device according to claim 1, wherein the first planarization layer further includes a second open area through an entire thickness of the first planarization layer, and the display device further comprising:
a reflection plate connected to a pixel circuit of the display panel, the reflection plate in contact with the connection electrode through the second open area.

8. The display device according to claim 5, wherein the second planarization layer includes a plurality of third open areas over the first electrode and the second electrode, and the connection electrode is in contact with at least one of the first electrode or the second electrode in the plurality of third open areas.

9. The display device according to claim 8, wherein the plurality of third open areas are in the first open area, and the connection electrode is in direct contact with the first planarization layer in the plurality of third open areas.

10. The display device according to claim 8, wherein the second planarization layer further includes a dummy open area that is non-overlapping with the first electrode and the second electrode.

11. The display device according to claim 8, wherein a long axis direction of the plurality of third open areas is in a first direction and a long axis direction of the first electrode and the second electrode is in a second direction that is different from the first direction.

12. The display device according to claim 8, wherein an area of the first electrode that is non-overlapped by the encapsulation layer in one of the plurality of third open areas is different from an area of the second electrode that is non-overlapped by the encapsulation layer in another one of the plurality of third open areas.

13. The display device according to claim 8, wherein the second planarization layer further includes a fourth open area though an entire thickness of the second planarization layer, and the display device further comprises:
a reflection plate connected to a pixel circuit of the display panel, the reflection plate in contact with the connection electrode through the fourth open area.

14. The display device according to claim 5, wherein a bottom surface of the first semiconductor layer includes a plurality of convex portions and a plurality of concave portions.

15. The display device according to claim 1, wherein the display panel includes an active area in which the plurality of subpixels are disposed and a non-active area that encloses the active area, and the active area further includes a plurality of gate driving areas that extend from the plurality of subpixels and includes a gate driver disposed therein.

16. The display device according to claim 15, wherein active layers of a plurality of transistors in the plurality of subpixels and active layers of a plurality of transistors in the gate driver include oxide semiconductor, amorphous silicon, or polysilicon.

17. The display device according to claim 16, wherein the plurality of transistors in the gate driver include active layers of different materials.

18. A display device comprising:
a substrate;
a thin film transistor on the substrate;
a lower planarization layer on the thin film transistor;
a light emitting diode configured to emit light, the light emitting diode electrically connected to the thin film transistor;
a first planarization layer that encloses the light emitting diode and includes a first portion that is in direct contact with a portion of a side surface of the light emitting diode and a second portion that extends from the first portion, the first portion of the first planarization layer having a thickness that is less than a thickness of the second portion of the first planarization layer; and
a second planarization layer that is on the light emitting diode and the first planarization layer.

19. The display device according to claim 18, wherein the second planarization layer is on the first portion of the first planarization layer and the second portion of the first planarization layer.

20. The display device according to claim 18, wherein the light emitting diode includes:
a first semiconductor layer;
a second semiconductor layer on the first semiconductor layer;
an emission layer between the first semiconductor layer and the second semiconductor layer;
a first electrode on the first semiconductor layer and is spaced apart from the emission layer;
a second electrode on the second semiconductor layer; and
an encapsulation layer that encloses a first part of a side surface of the first semiconductor layer, the emission layer, the second semiconductor layer, the first electrode, and the second electrode.

21. The display device according to claim 20, wherein a second part of the side surface of the first semiconductor layer is non-overlapping with the encapsulation layer and the first planarization layer is in direct contact with the second part of the side surface that is non-overlapping with the encapsulation layer.

22. The display device according to claim 20, further comprising:
a first connection electrode in contact with the second electrode; and
a second connection electrode in contact with the first electrode to electrically connect the light emitting diode with the thin film transistor.

23. The display device according to claim 22, wherein the first connection electrode and the second connection electrode are in direct contact with the first portion of the first planarization layer.
